(19) United States
(12) Patent Application Publication
(10) Pub. No.: US 2012/0320542 A1
(43) Pub. Date: Dec. 20, 2012

(54) DISPLAY DEVICE AND METHOD FOR MANUFACTURING THE SAME

(76) Inventors: Chang-Yong Jeong, Yongin-city (KR); Jae-Seob Lee, Yongin-city (KR); Yong-Hwan Park, Yongin-city (KR); Kyung-Mi Kwon, Yongin-city (KR)

(21) Appl. No.: 13/470,083

(22) Filed: May 11, 2012

(30) Foreign Application Priority Data
Jun. 16, 2011 (KR) 10-2011-0058708

(51) Int. Cl. H05K 7/06; B32B 38/10; B32B 37/12; H05K 7/00; H05K 1/02

(52) U.S. Cl. 361/749; 361/748; 361/783; 156/60; 156/242; 156/241; 156/234

(57) ABSTRACT

A display device includes: a substrate having a bonding area at an edge of the substrate; a conductive pad on the bonding area of the substrate; an external connection member having a connection area bonded with the bonding area of the substrate; a bump in the connection area of the external connection member at a side of the external connection member facing the conductive pad; and an anisotropic conductive film selectively disposed between the conductive pad and the bump and forming an electrical connection between the conductive pad and the bump.

### CROSS-REFERENCE TO RELATED APPLICATION

This application claims priority to and the benefit of Korean Patent Application No. 10-2011-0058708 filed in the Korean Intellectual Property Office on Jun. 16, 2011, the entire contents of which are incorporated herein by reference.

### BACKGROUND

1. Field

Embodiments of the present invention relate generally to a display device in which an integrated circuit chip or a flexible printed circuit board is installed through an anisotropic conductive film.

2. Description of Related Art

Recently, flat panel displays have been in the spotlight as widely used display devices. Types of portable flat panel displays include an organic light emitting diode (OLED) display, a liquid crystal display (LCD), an electrophoretic display, etc.

In most display devices, an integrated circuit chip or a flexible printed circuit board is bonded to an edge of a panel. In further detail, the integrated circuit chip is typically directly bonded using a chip on glass (COG) method on the panel through an anisotropic conductive film (ACF), or a tape carrier package (TCP) where an integrated circuit is installed or a chip on film (COF) is connected to the panel through the ACF.

However, as the resolution of the display device is increased and the non-display area of the display device is decreased, the width of wires is decreased and a distance between the wires is decreased. Thus, it is difficult to stably arrange and bond a pad of a substrate and a bump of an integrated circuit chip or flexible printed circuit board through an anisotropic conductive film.

The above information disclosed in this Background section is only for enhancement of understanding of the background of the described technology and therefore it may contain information that does not form the prior art that is already known in this country to a person of ordinary skill in the art.

### SUMMARY

Embodiments of the present invention have been made in an effort to provide a display device that can stably bond an integrated circuit chip or a flexible printed circuit board through an anisotropic conductive film.

A display device according to an exemplary embodiment includes: a substrate having a bonding area at an edge of the substrate; a conductive pad on the bonding area of the substrate; an external connection member having a connection area bonded with the bonding area of the substrate; a bump in the connection area of the external connection member at a side of the external connection member facing the conductive pad; and an anisotropic conductive film selectively disposed between the conductive pad and the bump and forming an electrical connection between the conductive pad and the bump.

The display device may further include an insulating layer on the substrate, the insulating layer having an opening, the opening wholly or partially exposing the conductive pad. The anisotropic conductive film may be not overlapped with the insulating layer.

The display device may further include an adhesive layer at a side of the bump facing the substrate, the adhesive layer contacting the anisotropic conductive film.

The external connection member may be an integrated circuit chip or a flexible printed circuit board.

In another embodiment of the present invention, a manufacturing method of a display device according to an exemplary embodiment includes: preparing a substrate having a bonding area at an edge of the substrate and a conductive pad on the bonding area; preparing an external connection member having a connection area and a bump on the connection area, the bump being adapted to form an electrical connection; forming an adhesive layer at one side of the bump; selectively disposing an anisotropic conductive film (ACE) on the bump and on the adhesive layer; and bonding the substrate to the external connection member, the conductive pad and the bump being disposed opposite to each other and electrically connected with each other, and the selectively disposed anisotropic conductive film being interposed between the conductive pad and the bump.

The manufacturing method may further include forming an insulating layer, the insulating layer wholly or partially exposing the conductive pad on the substrate.

The adhesive layer may be formed at one side of the bump using an imprint method.

The external connection member may be an integrated circuit chip or a flexible printed circuit board.

In the manufacturing method of the display device, the anisotropic conductive film may be selectively disposed on the bump by attaching the anisotropic conductive film formed on a carrier film to the connection area of the external connection member where the bump is formed, together with the carrier film, and then detaching the carrier film.

Adhesion between the adhesive layer formed at one side of the bump and the anisotropic conductive film may be stronger than adhesion between the anisotropic conductive film and the carrier film.

In the manufacturing method of the display device, the selectively disposing of the anisotropic conductive film on the bump may include: preparing a mask having an opening and a shield; arranging the mask on the connection area to make the opening correspond to the bump; and spraying anisotropic conductive materials through the mask and toward the bump.

The anisotropic conductive materials may be sprayed through an air gun.

A manufacturing method of a display device according to another exemplary embodiment includes: preparing a substrate having a bonding area at an edge of the substrate and a conductive pad on the bonding area; preparing an anisotropic conductive film (ACE) on a carrier film, the ACF including a photosensitive material; attaching the ACF, together with the carrier film, to the bonding area of the substrate where the conductive pad is formed; irradiating an ultraviolet ray through the substrate and toward the anisotropic conductive film, to cure portions of the anisotropic conductive film not blocked from the ultraviolet ray by the conductive pad; selectively disposing the anisotropic conductive film on the conductive pad by removing the cured anisotropic conductive film together with the carrier film; preparing an external connection member having a connection area and a bump in the connection area, the bump being configured to form an electrical connection; and bonding the substrate to the external connection member, the conductive pad and the bump being disposed opposite to each other, the selectively disposed anisotropic conductive film being interposed between the conductive pad and the bump.

The manufacturing method of the display device may further include forming an insulating layer having an opening that wholly or partially exposes the conductive pad on the substrate.

The external connection member may be an integrated circuit chip or a flexible printed circuit board.

According to the exemplary embodiments, the display device can stably bond an integrated circuit chip or a flexible printed circuit board.

### BRIEF DESCRIPTION OF THE DRAWINGS

FIG. 1 is a cross-sectional view of a display device according to a first exemplary embodiment of the present invention.

FIG. 2 to FIG. 6 are cross-sectional views sequentially illustrating a manufacturing method of the display device of the embodiment illustrated in FIG. 1.

FIG. 7 is a cross-sectional view of a manufacturing method of a display device according to a second exemplary embodiment of the present invention.

FIG. 8 is a cross-sectional view of a part of a display device according to a third exemplary embodiment of the present invention.

FIG. 9 to FIG. 11 are cross-sectional views sequentially illustrating the manufacturing method of the display device of the embodiment illustrated in FIG. 8.

### DETAILED DESCRIPTION

The present invention will be described more fully hereinafter with reference to the accompanying drawings, in which exemplary embodiments of the invention are shown. As those skilled in the art would realize, the described embodiments may be modified in various different ways, all without departing from the spirit or scope of the present invention.

Further, in the exemplary embodiments, like reference numerals designate like elements throughout the specification representatively in a first exemplary embodiment and only elements other than those of the first exemplary embodiment will be described.

The drawings and description are to be regarded as illustrative in nature and not restrictive. Like reference numerals designate like elements throughout the specification.

In addition, the size and thickness of each component shown in the drawings are arbitrarily shown for understanding and ease of description. However, the present invention is not limited to exemplary embodiments. It will be understood that when an element such as a layer, film, region, or substrate is referred to as being “on” another element, it can be directly on the other element or intervening elements may also be present.

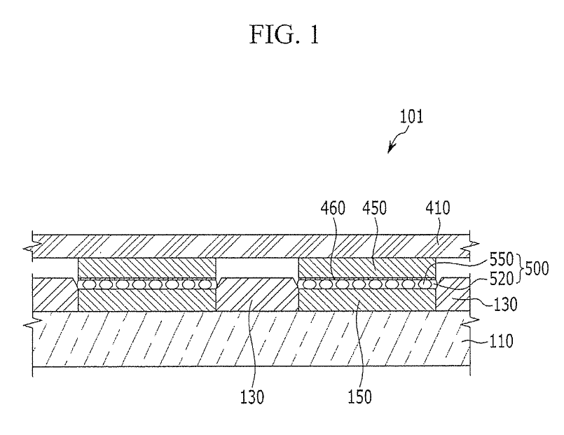

Hereinafter, a display device 101 according to a first exemplary embodiment of the present invention will be described with reference to FIG. 1.

As shown in FIG. 1, the display device 101 includes a substrate 110 and an external connection member 410 bonded with the substrate 110. Here, the external connection member 410 may be an integrated circuit chip or a flexible printed circuit board (FPCB). In the embodiment shown in FIG. 1, the external connection member 410 is a flexible printed circuit board.

The substrate 110 is divided into a display area where a display element is formed and a non-display area formed at the periphery of the display area. Various types of display elements that can be formed on the substrate 110 and that are known to a person skilled in the art may be used. For example, the types of display elements include an organic light emitting display element, a liquid crystal display, an electrophoretic display element, and the like. A part of the non-display area may be used as a bonding area. The bonding area is disposed at an edge of the substrate 110. The external connection member 410 such as an integrated circuit chip or a flexible printed circuit board is bonded to the bonding area.

A conductive pad 150 is formed in the bonding area of the substrate 110. The conductive pad 150 is configured to form a connection (e.g., an electrical connection) with the external connection member 410. In addition, an insulating layer 130 having an opening that wholly or partially exposes the conductive pad 150 is formed on the substrate 110.

The external connection member 410 includes a connection area bonded with the bonding area of the substrate 110. A bump 450 is formed in the connection area. The bump 450 is disposed opposite to the conductive pad 150 of the substrate 110 (e.g., on a portion of the external connection member 410 facing the conductive pad 150 of the substrate 110), and electrically connected with the conductive pad 150 through an anisotropic conductive film (ACE) 500. The anisotropic conductive film 500 includes a binder 520 and a conductive ball 550 (or a plurality of conductive balls).

In the first exemplary embodiment, an adhesive layer 460 is formed at one side of the bump 450 (e.g., a side of the bump facing the conductive pad 150 and facing away from the external connection member 410), arranged opposite to the conductive pad 150 and contacting the anisotropic conductive film 500. The adhesive layer 460 is disposed between the anisotropic conductive film 500 and the bump 450.

In addition, in the first exemplary embodiment, the anisotropic conductive film 500 is selectively disposed between the bump 450 and the conductive pad 150, except for an area (or areas) covered by the insulating layer 130 (e.g., the anisotropic conductive film is disposed such that it does not overlap with the insulating layer and a surface of the insulating layer facing the external connection member).

With such a configuration, the display device 101 according to the first exemplary embodiment has a stable bond between the substrate 110 and the external connection member 410 such as an integrated circuit chip or a flexible printed circuit board.

According to the first exemplary embodiment, the external connection member 410 can be stably bonded (e.g., to the substrate 110) through the anisotropic conductive film 500 even when the size of the conductive pad 150 is decreased and a distance between conductive pads 150 is decreased to increase the resolution of the display device 101 or to reduce or minimize the non-display area of the display device 101.

In contrast to the first exemplary embodiment of the present invention, when the anisotropic conductive film 500 is disposed over the entire insulating layer 130 rather than being selectively disposed between the conductive pad 150 and the bump 450, the anisotropic conductive film 500 disposed at undesired locations, such as on the insulating layer 130, separates the substrate 110 and the external connection member 410 more than necessary (e.g., increases the distance between the substrate 110 and the external connection member 410) so that the conductive pad 150 and the bump 450 may not be stably connected.

On the other hand, according to the first exemplary embodiment of the present invention, although the anisotropic conductive film 500 is selectively disposed at a desired location (or locations) to reduce or minimize the sizes of the conductive pad 150, the bump 450 and the distance therebetween, the conductive pad 150 and the bump 450 can be stably connected to each other.

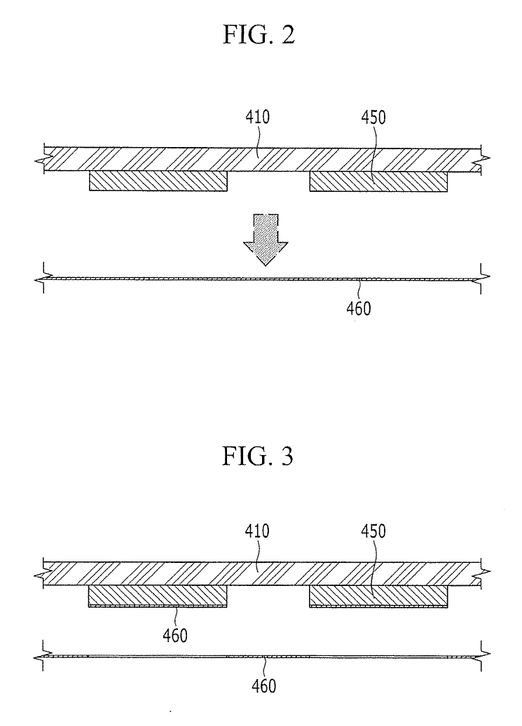

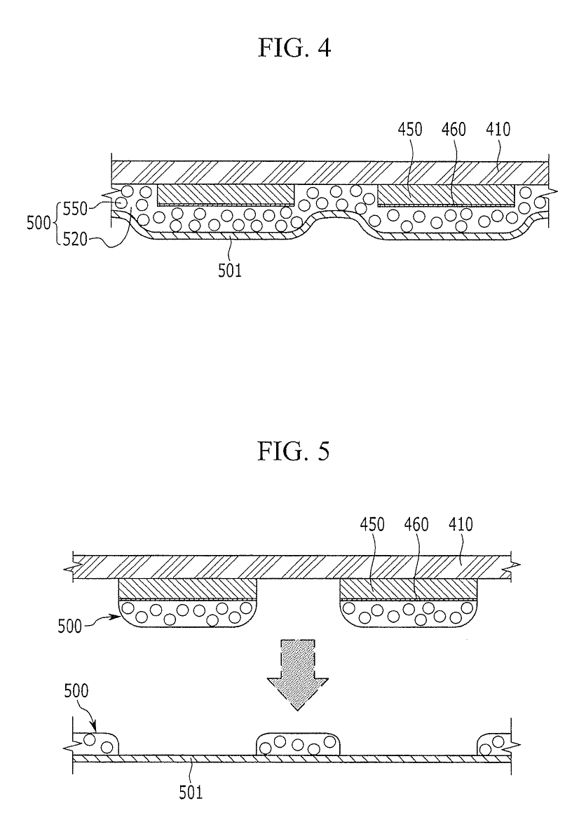

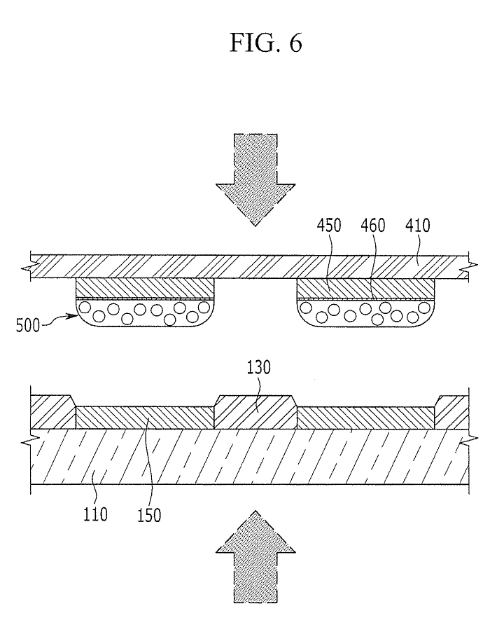

Hereinafter, a manufacturing method of the display device 101 according to the first exemplary embodiment of the present invention will be described with reference to FIG. 2, FIG. 3, FIG. 4, FIG. 5, and FIG. 6.

First, as shown in FIG. 2, the external connection member 410 where the bump 450 is formed for electrical connection is prepared. Then, as shown in FIG. 3, the adhesive layer 460 is formed at one side of the bump 450 using an imprint method. Details of the imprint method would be known to a person skilled in the art.

Next, as shown in FIG. 4, the anisotropic conductive film 500 formed on a carrier film 501 is attached together with the carrier film 501 to the connection area of the external connection member 410 where the bump 450 is formed. In this case, adhesion between the adhesive layer 460 formed at one side of the bump 450 and the anisotropic conductive film 500 is stronger than adhesion between the carrier film 501 and the anisotropic conductive film 500. Then, as shown in FIG. 5, when the carrier film 501 is detached, the anisotropic conductive film 500 is selectively disposed on the bump 450 (e.g., the anisotropic conductive film 500 is not disposed at portions of the external connection member 410 where the bump 450 is not located). Because the adhesion between the adhesive layer 460 and the anisotropic conductive film 500 is stronger than the adhesion between the carrier film 501 and the anisotropic conductive film 500, the anisotropic conductive film 500 remains on the bump 450 where the adhesive layer 460 is formed even though the carrier film 501 is detached.

Next, as shown in FIG. 6, the substrate 110 and the external connection member 410 are bonded to each other for the conductive pad 150 and the bump 450 to be disposed opposite to each other and electrically connected, interposing the anisotropic conductive film 500 therebetween. In this case, the anisotropic conductive film 500 is compressed with high pressure and high temperature, thus causing it to be cured. For example, the anisotropic conductive film 500 can be pressure-cured with a pressure of 75 kgf and a temperature of 200° C. The conductive pad 150 and the bump 450 are electrically connected by the conductive ball 550 of the pressure-cured anisotropic conductive film 500.

With such a manufacturing method according to one embodiment of the present invention, the display device 101 can have a stable bond between the external connection member 410 such as an integrated circuit chip or a flexible printed circuit board and a substrate 110.

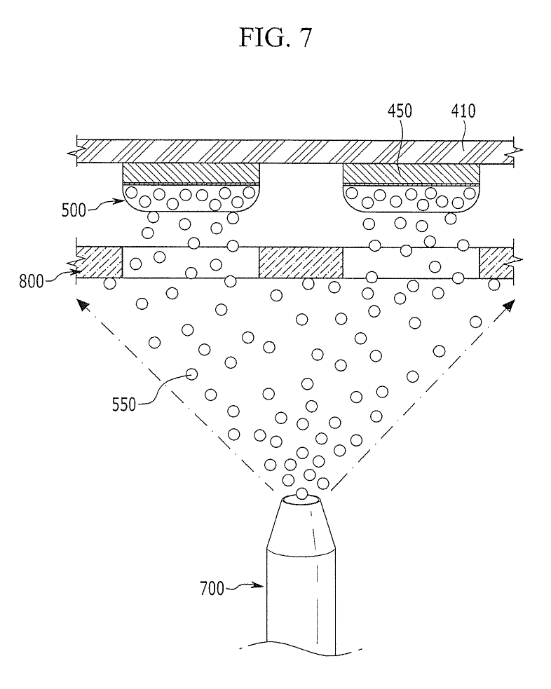

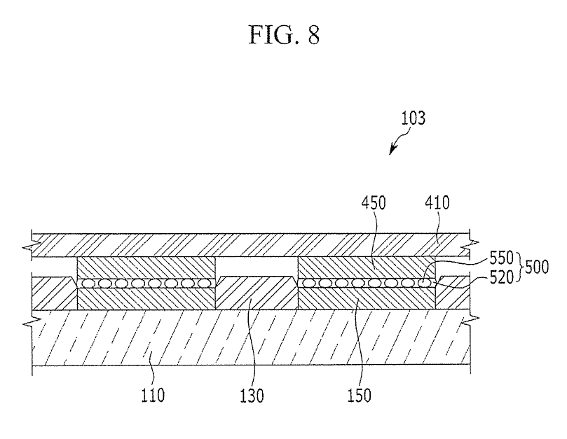

Hereinafter, a second exemplary embodiment of the present invention will be described with reference to FIG. 7.

A structure of a display device according to the second exemplary embodiment of the present invention is substantially the same as that of the display device of the first exemplary embodiment. Description of the manufacturing method according to the second exemplary embodiment will be focused on a difference from the manufacturing method according to the first exemplary embodiment.

First, an adhesive layer 460 is formed at one side of a bump 450 using the same method described in the first exemplary embodiment with reference to FIG. 2 and FIG. 3.

Next, as shown in FIG. 7, a mask 800 having an opening and a shield is prepared. The mask 800 may be made of metal or acryl, and may be formed in a film form. In this case, a pattern of the opening (or openings) corresponds to a pattern of the bump 450 (or bumps 450) (e.g., the openings are aligned with the bumps 450). The mask 800 is disposed on a connection area of an external connection member 410 at a side where the bump 450 is formed for the opening to be disposed opposite to (e.g., facing) the bump 450. Then, anisotropic conductive materials 500 are sprayed toward the bump 450, with the mask 800 interposed therebetween. In this case, the anisotropic conductive materials 500 are sprayed through an air gun 700. The anisotropic conductive materials 500 can be sprayed through the air gun 700 using the same method as that for spraying electrophoretic balls during a manufacturing method of an electrophoretic display.

When the sprayed anisotropic conductive materials 500 are selectively disposed with a desired thickness on the bump 450, the substrate 110 and the outer connection member 410 are bonded to each other for the conductive pad 150 and the bump 450 to be disposed opposite to each other and electrically connected with each other using the method described with reference to FIG. 6.

With such a manufacturing method, the external connection member 410 such as an integrated circuit chip or a flexible printed circuit board can be stably bonded to a substrate 110.

Hereinafter, a third exemplary embodiment of the present invention will be described with reference to FIG. 8.

As shown in FIG. 8, a display device 103 according to the third exemplary embodiment is substantially the same as the display device 101 according to the first exemplary embodiment, except that the adhesive layer 460 is not provided between an anisotropic conductive film 500 and a bump 450 of an external connection member 410. That is, the adhesive layer 460 is omitted in the third exemplary embodiment.

Nevertheless, in the third exemplary embodiment of the present invention, the anisotropic conductive film 500 is selectively disposed between the bump 450 and a conductive pad 150, except an area covered by an insulating layer 130.

With such a configuration, the display device 103 can stably bond the external connection member 410 such as an integrated circuit chip or a flexible printed circuit board to the substrate 110.

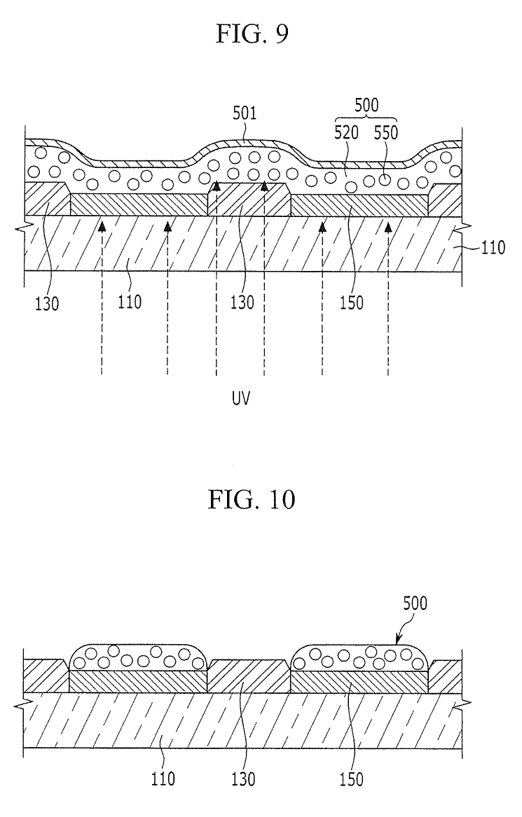

Hereinafter, a manufacturing method of the display device 103 according to the third exemplary embodiment of the present invention will be described with reference to FIG. 9 and FIG. 10.

First, as shown in FIG. 9, the conductive pad 150 is formed on a bonding area disposed at an edge of the substrate 110. Then, an insulating layer 130 having an opening that wholly or partially exposes the conductive pad 150 is formed on the substrate 110.

Next, an anisotropic conductive film (ACF) 500 formed on a carrier film 501 is prepared. In the third exemplary embodiment of the present invention, the anisotropic conductive film 500 includes a photosensitive material. That is, the anisotropic conductive film 500 includes a binder 520 containing a photosensitive material and a conductive ball 550.

Next, the anisotropic conductive film 500 is attached together with the carrier film 501 to the bonding area of the substrate 110 where the conductive pad 150 is formed. Then, the anisotropic conductive film 500 is irradiated with an ultraviolet (UV) ray through the substrate 110. In one embodiment, the conductive pad 150 formed in the substrate 110 blocks the ultraviolet ray. Thus, the anisotropic conductive film 500 disposed on the conductive pad 150 is not exposed to the ultraviolet ray. On the other hand, a portion of the anisotropic conductive film 500 where the ultraviolet (UV) ray is not blocked by the conductive pad 150 is exposed to the ultraviolet ray and therefore the exposed portion is cured.

Next, when the carrier film 501 is detached from the substrate 110, the cured portion of the anisotropic conductive film 500 is separated from the substrate 110, together with the carrier film 501. Therefore, the anisotropic conductive film 500 can be selectively disposed on the conductive pad 150.

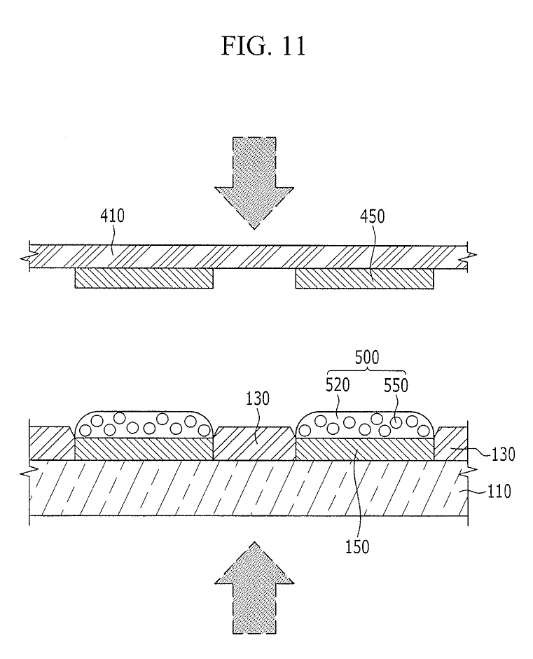

Next, as shown in FIG. 11, an external connection member 410 where a bump 450 is formed for electrical connection is prepared, and then the substrate 110 and the external connection member 410 are bonded to each other for the conductive pad 150 and the bump 450 to be disposed opposite to each other and electrically connected with each other, with the selectively disposed anisotropic conductive film 500 interposed therebetween. This process may be carried out using the same method described in the first exemplary embodiment of the present invention.

With such a manufacturing method, the display device 103 can have a stable bond between the substrate 110 and the external connection member 410 such as an integrated circuit chip or a flexible printed circuit board.

While this disclosure has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims and equivalents thereof.

<Description of selected reference numerals>

| | |
|---|---|
| 101, 103: display device | 110: substrate |
| 130: insulation layer | 150: conductive pad |
| 410: external connection member | 450: bump |
| 460: adhesive layer | 500: anisotropic conductive film |

What is claimed is:

1. A display device comprising:
a substrate having a bonding area at an edge of the substrate;
a conductive pad on the bonding area of the substrate;
an external connection member having a connection area bonded with the bonding area of the substrate;
a bump in the connection area of the external connection member at a side of the external connection member facing the conductive pad; and
an anisotropic conductive film selectively disposed between the conductive pad and the bump and forming an electrical connection between the conductive pad and the bump.

2. The display device of claim 1, further comprising an insulating layer on the substrate, the insulating layer having an opening, the opening wholly or partially exposing the conductive pad,
wherein the anisotropic conductive film is not overlapped with the insulating layer.

3. The display device of claim 1, further comprising an adhesive layer at a side of the bump facing the substrate, the adhesive layer contacting the anisotropic conductive film.

4. The display device of claim 1, wherein the external connection member is an integrated circuit chip or a flexible printed circuit board.

5. A manufacturing method of a display device, the method comprising:
preparing a substrate having a bonding area at an edge of the substrate and a conductive pad on the bonding area;
preparing an external connection member having a connection area and a bump on the connection area, the bump being adapted to form an electrical connection;
forming an adhesive layer at one side of the bump;
selectively disposing an anisotropic conductive film (ACF) on the bump and on the adhesive layer; and
bonding the substrate to the external connection member, the conductive pad and the bump being disposed opposite to each other and electrically connected with each other and the selectively disposed anisotropic conductive film being interposed between the conductive pad and the bump.

6. The manufacturing method of the display device of claim 5, further comprising forming an insulating layer, the insulating layer wholly or partially exposing the conductive pad on the substrate.

7. The manufacturing method of the display device of claim 5, wherein the adhesive layer is formed at one side of the bump using an imprint method.

8. The manufacturing method of the display device of claim 5, wherein the external connection member is an integrated circuit chip or a flexible printed circuit board.

9. The manufacturing method of claim 5, wherein the anisotropic conductive film is selectively disposed on the bump by attaching the anisotropic conductive film formed on a carrier film to the connection area of the external connection member where the bump is formed, together with the carrier film, and then detaching the carrier film.

10. The manufacturing method of claim 9, wherein adhesion between the adhesive layer formed at one side of the bump and the anisotropic conductive film is stronger than adhesion between the anisotropic conductive film and the carrier film.

11. The manufacturing method of the display device of claim 5, wherein the selectively disposing of the anisotropic conductive film on the bump comprises:
preparing a mask having an opening and a shield;
arranging the mask on the connection area to make the opening correspond to the bump; and
spraying anisotropic conductive materials through the mask and toward the bump.

12. The manufacturing method of the display device of claim 11, wherein the anisotropic conductive materials are sprayed through an air gun.

13. A manufacturing method of a display device comprising:
preparing a substrate having a bonding area at an edge of the substrate and a conductive pad on the bonding area;
preparing an anisotropic conductive film (ACF) on a carrier film, the ACF including a photosensitive material;
attaching the ACF, together with the carrier film, to the bonding area of the substrate where the conductive pad is formed;
irradiating an ultraviolet ray through the substrate and toward the anisotropic conductive film, to cure portions of the anisotropic conductive film not blocked from the ultraviolet ray by the conductive pad;
selectively disposing the anisotropic conductive film on the conductive pad by removing the cured anisotropic conductive film together with the carrier film;
preparing an external connection member having a connection area and a bump in the connection area, the bump being configured to form an electrical connection; and
bonding the substrate to the external connection member, the conductive pad and the bump being disposed opposite to each other, the selectively disposed anisotropic conductive film being interposed between the conductive pad and the bump.

14. The manufacturing method of the display device of claim 13, further comprising forming an insulating layer having an opening that wholly or partially exposes the conductive pad on the substrate.

15. The manufacturing method of the display device of claim 13, wherein the external connection member is an integrated circuit chip or a flexible printed circuit board.
